(19) United States
(12) Patent Application Publication
(10) Pub. No.: US 2004/0005001 A1
(43) Pub. Date: Jan. 8, 2004

(54) Gain adaptive equalizer

(76) Inventors: Keith R. Jones, Ramona, CA (US); Gilberto Isaac Sada Trevino, San Diego, CA (US); William W. Jones, San Diego, CA (US)

Correspondence Address: WEIDE & MILLER, LTD., 7251 W. LAKE MEAD BLVD., SUITE 530, LAS VEGAS, NV, 89128, US

(21) Appl. No.: 10/188,615

(22) Filed: Jul. 2, 2002

(51) Int. Cl. H03H 7/30

(52) U.S. Cl. 375/232

(57) ABSTRACT

A method and apparatus is provided for processing a signal to remove or reduce the unwanted effects of transmission through the transmission line. To reverse, negate or counter the attenuating properties of transmission through a transmission line the method and apparatus described herein determines the amount of amplification or a gain value required to restore one or more aspect of the signal to a desired or a pre-transmission level. Characterization of the line, based on the gain value, determines one or more filter coefficients. Based on the one or more coefficients, a filtered modifies the signal to reverse the effects of the channel. In one embodiment the peak value or an average magnitude of the received signal is detected to determine the gain value. Dampening may optionally be included to limit the amount of filter modification that may occur on the signal in a clock cycle.

### FIELD OF THE INVENTION

The invention relates to data communication and in particular to an efficient method and apparatus for adaptive signal equalization.

### RELATED ART

While new and emerging technologies are capable of utilizing modern hardware and advances in signal processing, communication standards and systems, which were developed in the past, are based on the state of the art as it existed in the past. At the time these standards were developed and adopted for use they offered the latest in communication technology. Today however, these prior standards are forced to compete with modern, high speed communication systems. In many instances, prior technology has been pushed to compete with modern communication systems.

While prior communication technology may not realize the speed advantages of a modern communication system, it does enjoy the advantage of widespread deployment. Traditionally, existing communication technology is reliable and at a desired price-point. Moreover, communication channels are readily available to support the existing communication technology. Hence existing technology may be available in locations where the latest communication technology has not yet been deployed.

By way of example, T1 and E1 communication systems, while widely deployed, suffer from the drawback of lacking a training sequence during startup or after other periods of non-use. Without a proper training sequence a communications receiver module, such as an equalizer, has difficulty determining channel conditions at the time of the communication session. The difficulties posed by the lack of a training sequence can be compounded by lack of a scrambler and/or by use of a three level line code, such as Alternate Mark Inversion, with zero volts as a valid level. As a result, a long string of zeros may prevent proper equalization. This may cause the channel analysis process to stop prior to convergence at an optimal solution.

As a result of these drawbacks of prior technologies, such as by way of example systems without advanced channel estimation technology, operation may result in less than desired communication performance or prevent signal transmission over long distances. There is thus a need for an efficient equalizer structure to overcome the drawbacks in the prior art. Modern communication technology may also benefit from the advances discussed and claimed below. A need also exists for an efficient equalizer structure to enable modern communication systems to operate at higher speeds with less error and over longer distances.

### SUMMARY

To overcome the drawbacks of the prior art the method and apparatus described herein provides an adaptive equalizer system. The adaptive equalizer system monitors and analyzes a received signal on an ongoing basis. The received signal may arrive via any medium capable of transmitting a signal or in any coding scheme. The adaptive equalizer system processes the signal to reverse, negate, or offset the effects of transmission through the channel. In one embodiment the processing is frequency dependant such that not all frequencies of the signal are modified equally.

In one embodiment an equalizer, that is configured to process a received, signal comprises an amplifier configured to amplify the received signal to create an amplified signal at a predetermined power level. In one embodiment the amount of amplification is the gain value. The equalizer may further include a filter configured to modify the amplified signal on a frequency dependant basis to generate a filtered signal. The filter may be characterized by one or more coefficients. A control unit is also included and is configured to control the gain value of the amplifier based on the magnitude of the received signal, the amplified signal, or the filtered signal and obtain the one or more coefficient values based on the gain value or other aspect of the signal.

In one embodiment filter comprises a two tap transversal filter and the amplifier is configured to amplify all frequencies an equal amount. In one embodiment the equalizer further includes a memory configured to store the one or more coefficient values such that the control unit is configured to analyze the gain value and, based on the gain value, retrieve the one or more coefficient values from the memory and provide the one or more coefficient values to the filter. It is contemplated that the filter may amplify or attenuate on a frequency dependant basis. In another embodiment, a transmission line equalizer is provided that comprises an amplifier configured to amplify a received signal based on a gain value to create an amplified signal and an equalizer configured to receive one or more coefficients and modify the amplified signal based on the one or more coefficients. The system further includes a peak detector configured to receive feedback from the equalizer and determine its peak value. The system also includes a controller, connected to the peak detector and responsive to the peak value, that is configured to provide the one or more coefficients to the equalizer, as well as the gain value to the amplifier.

In one embodiment this system is configured so that the equalizer is configured to increase modification to the high frequency portion of the amplified signal as the peak value, detected by the peak detector, decreases. In one embodiment the system further includes a memory in communication with the controller, the memory configured to store one or more coefficients and predefined thresholds. The one or more coefficients may be selected based on which two threshold values the peak occurs between. In one configuration the one or more coefficients create an equalizer having a frequency response inverse to the transmission line.

In yet another embodiment a computer program product is provided that comprises a computer useable medium having computer program logic recorded thereon for providing signal analysis and compensation. This embodiment comprises computer program code logic configured to analyze a signal received over a channel to determine a gain level required restore the signal to predetermined level and computer program code logic configured to perform a look-up operation in a memory to obtain one or more filtering control values based on the gain level. Additional computer program code logic is configured to filter the signal based on the filtering control values to selectively amplify or attenuate portions of the signal. In one embodiment the predetermined level comprises a signal power level at which the signal was transmitted. The computer program control logic that is configured to filter the signal may execute on a digital signal processor and the computer program control logic configured to filter may comprise computer program control logic configured to increase the power level of high frequency portions of the signal as the gain level increases.

A system for reversing attenuation of a signal resulting from transmission through a channel according to the method and apparatus that comprises a comparator configured to compare one or more aspects of the signal to one or more predetermined values and a memory configured to store coefficient values. The system further comprises a controller in communication with the comparator wherein the controller is configured to retrieve from the memory one or more coefficient values based on the comparison performed by the comparator and a filter connected to the controller, wherein the filter, responsive to the one or more coefficient values, reverse the effects of the channel.

This system may be configured such that the filter comprises an adaptive filter configured to utilize one or more coefficient values. The comparator may compare a peak value of the signal to one or more reference values to determine which of the one or more coefficient values to retrieve from memory. In another embodiment the comparator compares a threshold value of the signal to one or more reference values to determine which of the one or more coefficient values to retrieve from memory. The controller may comprise a processor. It is contemplated that a dampening circuit may be included to limit the maximum rate of change for the one or more coefficient values.

A method for processing a received signal to negate the effect on the signal from transmission through a channel may also be achieved. The method may comprise receiving a signal and analyzing the amplitude of the signal to determine an amount of effect on the signal from transmission through the channel. Thereafter, generating or retrieving one or more filter coefficients based on the amount of effect and filtering the signal, based on the one or more filter coefficients, to adjust the power level of the signal, on a frequency dependant basis, to thereby negate the effect on the signal from transmission through the channel.

This method may further comprise generating or retrieving one or more filter coefficients from a memory that is storing one or more filter coefficients. The filtering may comprise providing the signal to a two stage transversal filter. In one embodiment analyzing the signal comprises detecting a peak value of the signal and the generating or retrieving one or more filter coefficients from a memory is based on the peak value. Alternatively, analyzing the signal may comprise comparing the magnitude of the signal to a threshold. The gain may be adjusted such that the average difference between the magnitude of the signal and the threshold is minimized. It is contemplated that as the amplitude of the signal decreases the filtering increases the power level of high frequency portions of the signal more so than low frequency portions of the signal.

Another method of operation comprises adjusting the power level of signal portions located at different frequencies to offset the effect on the signal portions resulting from transmission through a channel. This method comprises receiving one or more signal portions, the signal portions comprising a signal transmitted over the channel. Next, the method amplifies the one or more signal portions based on a gain control value. The amplifying is intended to increase the power level of the one or more signal portions to a predetermined power level. The method may then analyze the one or more signal portions to determine the gain control value and generating one or more filter coefficients based on the gain control value. The method also modifies at least one of the one or more signal portions on a frequency dependant basis, based on the one or more filter coefficients, to offset the effect of transmission through the channel. In one embodiment the analyzing comprises determining a peak power level or an average power level of one or more signal portions. This may further include comparing the peak power level or the threshold power level to predetermined values and the generating comprises retrieving, based on the comparison, filter coefficients from a memory configured to stored filter coefficients.

In one variation, the modifying is performed by a pre-equalizer configured to utilize two filter coefficients. The amplifying may amplify all signal portions and wherein modifying the signal comprises modifying high frequencies portions of the signal more than low frequency portions of the signal. In one embodiment generating one or more frequency control value comprises comparing the gain value to one or more stored values and based on the comparison retrieving one or more filter coefficients from a memory.

Other systems, methods, features and advantages of the invention will be or will become apparent to one with skill in the art upon examination of the following figures and detailed description. It is intended that all such additional systems, methods, features and advantages be included within this description, be within the scope of the invention, and be protected by the accompanying claims.

### BRIEF DESCRIPTION OF THE DRAWINGS

The components in the figures are not necessarily to scale, emphasis instead being placed upon illustrating the principles of the invention. In the figures, like reference numerals designate corresponding parts throughout the different views.

FIG. 1 illustrates a plot of a signal's frequency response when transmitted over transmission lines of differing length.

FIG. 2 illustrates a block diagram of one example embodiment of an gain adaptive equalizer.

FIG. 3 illustrates a block diagram of an example embodiment of an adaptive equalizer with a peak detector.

FIG. 4 illustrates an example embodiment of the equalizer illustrated in FIG. 3.

FIG. 5 illustrates a block diagram of an alternative embodiment of an equalizer.

FIG. 6 illustrates an example plot of the frequency response of a hypothetical transmission line and the frequency response of an adaptive equalizer system.

FIG. 7 illustrates an operational flow diagram of one example method of operation of the invention.

FIG. 8 illustrates a block diagram of an example embodiment of a peak value control system.

FIG. 9 is an operational flow diagram of an example method of operation of the peak value control system shown in FIG. 8.

FIG. 10 illustrates an alternative embodiment of the invention.

FIG. 11 illustrates a block diagram of an example embodiment of a threshold detector.

### DETAILED DESCRIPTION

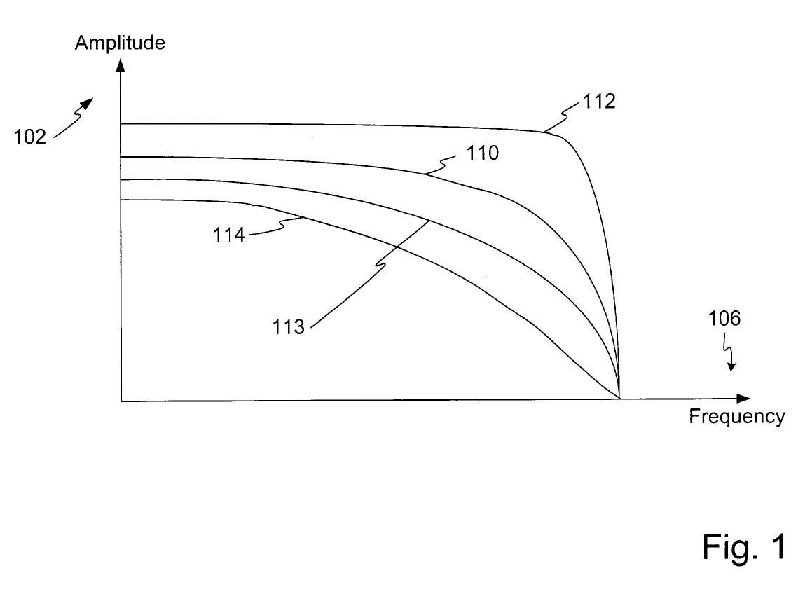

FIG. 1 illustrates a plot of an exemplary signal's frequency response when transmitted over transmission lines of differing length. In the plot of FIG. 1 signal amplitude is represented on the vertical axis 102 while frequency is represented on the horizontal axis 106. Signal plot 112 represents a plot of a transmitted signal provided to a line or channel.

Signal plot 110 is representative of the effect, on a signal, of a short line as compared to a transmitted signal. As can be seen a small amount of attenuation occur due to the short length of the line.

Signal plot 113 is representative of the frequency response of a line of medium length in response to an input signal 112. As can be seen more attenuation occurs as compared plot 110 since the line is longer. Moreover, a greater amount of attenuation occurs at high frequency portions of the signal.

Signal plot 114 is representative of the frequency response of a line of long length in response to the input signal 112. As can be seen, plot 114 representing the frequency response resulting from a more lengthy transmission line is more noticeably attenuated at all frequencies and especially attenuated at high frequencies. The method and apparatus described below overcomes the drawbacks associated with the varying level of signal attenuation that occurs during transmission and the lack of training sequence in some communication systems.

It can thus be seen that the amount of signal attenuation corresponds to transmission line length. As transmission line length increases, signal attenuation also increases. This relationship is frequency dependent in that higher frequency are attenuated more significantly as length increases than are lower frequencies in the signal.

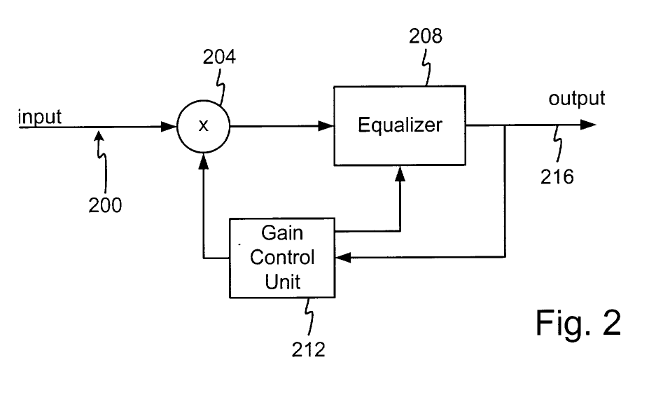

FIG. 2 illustrates a block diagram of one example embodiment of an adaptive equalizer. As shown an input 200 connects to a multiplier 204. The multiplier's output feeds into a filter or equalizer 208. In one embodiment the equalizer is a pre-equalizer. The output of the equalizer 208 is provided as an output for subsequent processing and also serves as an input to a gain control unit 212. The output of the gain control unit 212 feeds the gain value into the multiplier 204 and control signal to the equalizer.

The equalizer 208 may comprise any type equalization device or filter configured to increase or decrease the amplitude of one or more portions of a signal residing at select frequencies. In one embodiment the equalizer is configured to perform frequency dependant processing on the signal. In one embodiment the equalizer comprises a two tap transversal filter. The equalizer may be configured with any number of taps or coefficients.

In one embodiment the gain control unit 212 in conjunction with the multiplier 204 is configured to provide a variable amount of amplification or gain, constant across all frequencies, to the received signal. Any type gain control or power control system may be used. In one embodiment the gain control unit amplifies the received signal by an amount sufficient to restore the average power level of the received signal to predetermined level.

In one embodiment the amount of gain or amplification the gain control unit 212 applies is monitored and used as an indicator of the length of the line 200. For example, long channels more greatly attenuate a signal than a short channel. Hence if a significant level of gain is required to restore the received signal to a predetermined level, then it can be assumed that the channel is of the significant length. In this manner, based on the level of gain applied to the signal the channel may be characterized. This principle is discussed below in more detail.

In one embodiment, the input on line 200 comprises a signal sampled at twice the symbol rate or four times the symbol rate. The multiplier 204 receives this signal, provides gain, and passes the signal through to the equalizer 208. The equalizer is configured to filter the signal based on one or more equalizer coefficients. The output of the equalizer 208 is provided as feedback to the gain control unit 212. The gain control unit 212 adjusts the magnitude of the received signal by providing a multiplier signal to the multiplier 204. The multiplier signal is thus used to modify the input to the equalizer 208. In one embodiment, the gain control unit 212 provides an input to the equalizer 208 that sets or controls the equalizer coefficients.

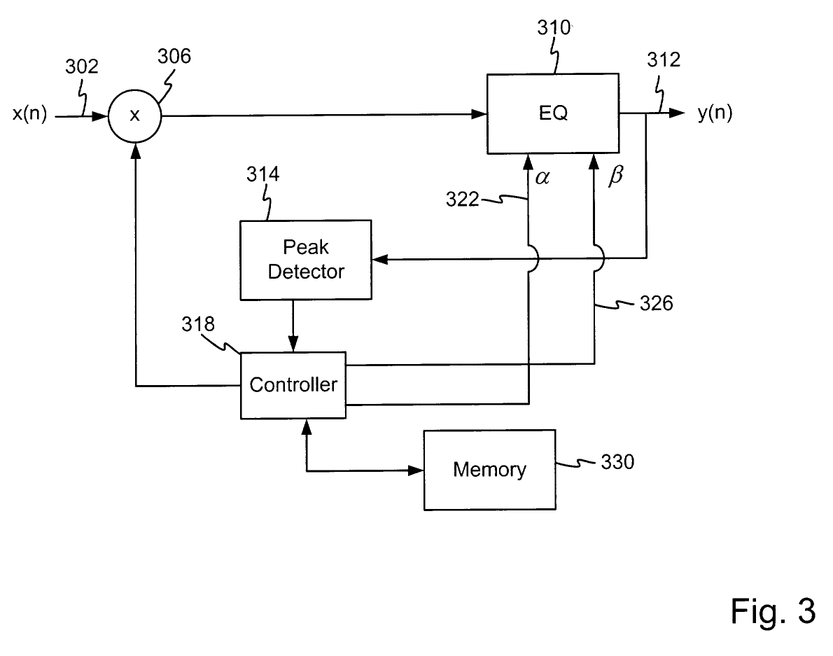

FIG. 3 illustrates a block diagram of an example embodiment of the invention having a peak detector. This is but one example embodiment and hence other embodiments are contemplated. An input 302 feeds into a multiplier 306. The multiplier 306 output connects to an equalizer 310. The equalizer 310 has an output 312 that feeds back into a peak detector 314.

The peak detector 314 also communicates with a controller 318. The controller computes the gain for the multiplier and the coefficients for the equalizer. The controller 318 also connects to the equalizer 310 via a first input 322 and a second input 326. Although two inputs 322, 326 are shown, it is contemplated that any number of inputs to the equalizer 310 may be implemented. The controller 318 may optionally communicate with a memory 330. The memory may comprise a register, RAM, flash memory, eprom, or any other type memory.

The equalizer 310 may comprise any type filter or device configured to selectively modify certain portions of a signal. In one embodiment the equalizer 310 comprises an adaptive equalizer. In one embodiment the equalizer 310 comprises a transversal filter. In one embodiment the equalizer selectively modifies a signal's frequency components. It is contemplated that the modification may be controlled by one or more coefficients or other control signals.

The peak detector 314 is configured to process or monitor the feedback signal from the equalizer 310 to determine a peak in the feedback signal. The peak detector 314 provides information regarding the peak value of the equalizer output to the controller 318. The controller adjusts the gain of the multiplier such that the peak value of the equalizer output is set to a certain level. The controller adjusts the equalizer coefficients based on this gain value.

In other embodiments the peak value of the signal may be monitored at any point in the processing. The controller 318 processes the peak information. In one embodiment the processing comprises comparing the peak information to one or more other values, such as thresholds, and thereby select an output based on the comparison.

The controller 318 may access the memory 330 to obtain threshold data and equalizer coefficients. In one embodiment the memory 330 stores data that is accessed by the controller 318 to generate or provide signals to the equalizer 310 over the first input 322 and the second input 326. In one embodiment the first input 322 and the second input 326 provides values α and β to the equalizer where the values α and β comprise tap values for an adaptive equalizer having two or more taps. The values α and β, when used as tap values, control the frequency response of the equalizer 310. In one embodiment the values α and β are updated or modified during operation of the system. Although two coefficients are shown, any number of coefficients may be provided. Two values are specified for purposes of discussion.

In another embodiment the system of FIG. 3 is configured without a memory 330 and the controller 318 is configured to calculate the input to the equalizer 310, in this embodiment the values α and β. In such an embodiment the controller 318 may execute one or calculations to determine the desired equalizer coefficients.

In one embodiment the controller 318 delays or dampens modification of the α and β values so that a significant or sudden change in the detected peak value does not cause a corresponding significant or sudden change in the α and β values.

As discussed, in one embodiment the values α and β correspond to tap values in a two-tap equalizer. The equalizer 310 may comprise any number of taps or stages. Through modification of the values α and β the equalizer 310 performance may be modified and controlled. In one embodiment, the equalizer's frequency response may be made inversely proportional to the channel response. When the system of FIG. 3 is included in a receiver as a pre-equalizer the equalizer coefficients may be selected, based on the gain value, to thereby negate the undesired channel frequency response. Hence, the equalizer 310 frequency response is inversely proportional to the channel attenuation on a frequency adapted basis.

In one embodiment the processing operates at 4 samples per second. Increasing the sampling rate captures more information of the received signal in short haul applications and supports effective clock recovery techniques. In one embodiment the filter is the cascade of a match filter (1+z⁻¹) and two first order high pass filters (1−αz⁻¹) and (1−βz⁻¹). In one embodiment the coefficients α and β are 4 bit numbers ranging form 0 to 15/16. In such an embodiment when α=β=0 then the filter reduces to a 4 sample per second filter matched to a transmitted return to zero pulse as would be expected at short line lengths. Increasing the coefficient values increase the amount of high frequency equalization. In one configuration, at short and medium length lines α=0 and β increases to 15/16. At longer line lengths α=15/16 and β increases. The increase may occur monotonically. Coefficients values may change during operation in real time. At start-up the initial settings may be based on the converged value of the automatic gain control loop.

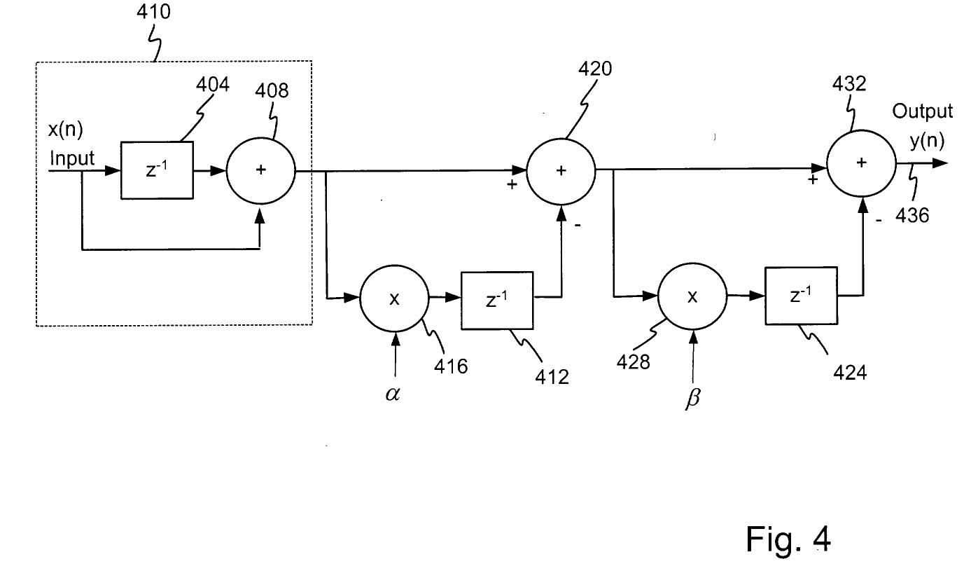

FIG. 4 illustrates an example embodiment of the equalizer 310 illustrated in FIG. 3. As shown, the input signal x(n) is provided to a first delay 404. The first delay 404 is configured to delay the incoming signal by one sampling clock cycle. Other units or amounts of delay may be introduced into the signal as necessary or desired to achieve the results described herein. The first delay unit 404 may comprise any type of delay. Example of the delay include, but are not limited to, a pipeline register or a shift register. The output of the first delay 404 connects to a first summing junction 408. The first summing junction 408 also receives a feed forward signal consisting of x(n). In one embodiment the first delay unit 404 and the first summing junction 408, enclosed by the dashed line may be collectively referred to as a matched filter 410 for the incoming signal. This matched filter 410 is thus the optimum receive filter when the received signal is distorted only by additive white Gaussian noise.

The first summing junction 408 outputs the combined signal into a first multiplier 416 and a summing junction 420. The output of the first multiplier 416 feeds into a second delay unit 412. The second delay unit 412 may comprise a unit similar to the first delay unit 404 or any other type of delay device that introduces an amount of delay into the received signal. In one embodiment the second delay device 412 introduces one sampling clock cycle of delay. Other amounts of delay, either greater than or less than a cycle may be introduced. The output of the second delay unit 412 feeds into a second summing junction 420.

The first multiplier 416 multiplies the output from the first summing junction 408 with a coefficient value α. The value α represents a filter control coefficient selected based on signal analysis or degree of processing required to manipulate the signal to a desired format. In one embodiment a is selected based on an amount of gain required to restore a received signal to a predetermined level or peak value. The effect of the α and β values are discussed below in greater detail.

The second summing junction 420 outputs the combined signal to a second multiplier 428 and a third summing junction 432. In one embodiment the second summing junction 420 subtracts the delay 412 output from the first summing junction 408 output. The output of the multiplier 428 connects to a third delay unit 424. The third delay unit 424 may comprise a unit similar to the first delay unit 404 or second delay unit 416 or any other type of delay device that introduces an amount of delay into the received signal. In one embodiment the third delay device 424 introduces one sampling clock cycle of delay. Other amounts of delay, either greater than or less than a cycle or period may be introduced. The output of the third delay unit 424 feeds into a third summing junction 432.

The input into the second multiplier 428 is multiplied by a value A. The third summing junction 432 combines its inputs and generates an output y(n) 436. In one embodiment the output from the delay 424 is subtracted from the output of the second summing junction 420.

The values of α and β are selected to control the equalizer frequency response. The values α and β tune the equalizer to output a signal with desired levels of energy located at desired frequencies. In one embodiment, equalizer is tuned to negate or reverse the effects of the channel. For example, by adjusting the values α and β the frequency response of the equalizer may be made to be the inverse of the channel. The α and β values that are selected control the frequency content of the output signal. In this manner the equalizer can negotiate the channel's tendency to attenuate higher frequencies to a greater degree than the lower frequencies.

In one embodiment the values for α and β are selected from two or more values stored in memory. The values may be predetermined. In one embodiment the output of the equalizer is analyzed by the peak detector shown in FIG. 3 and the peak value determines the values selected or calculated for α and β. Other aspects of the signal or other operations may be used to determine the values of α and β.

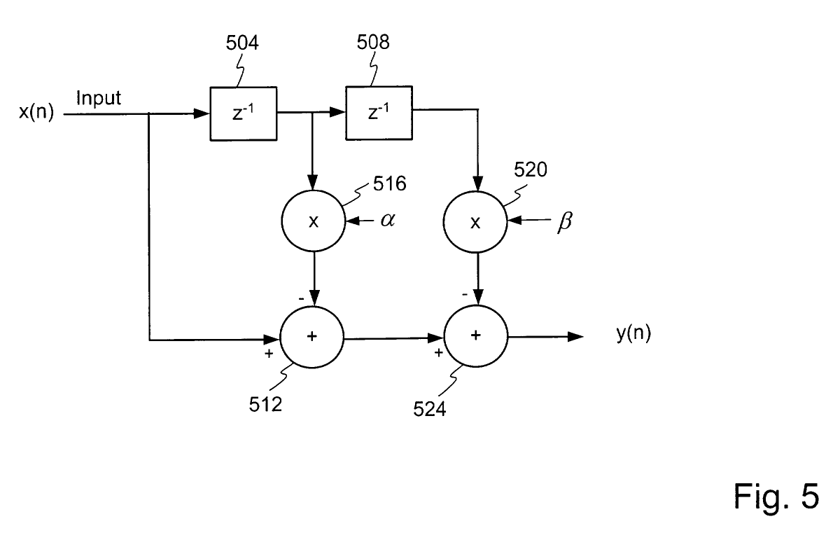

FIG. 5 illustrates a block diagram of an alternative embodiment of a equalizer. In this embodiment an input x(n) is provided to a first delay unit 504 and a first summing junction 512. The output of the first delay unit 504 is output to a second delay unit 508 and a multiplier 516. The multiplier 516 also receives a value α by which the input from the first delay unit 504 is multiplied. The output of the multiplier 516 is subtracted from the input x(n) in the summing junction 512. The output of the first summing junction 512 feeds into a second summing junction 524.

The input to the second delay unit 508 is delayed by any amount. In one embodiment the second delay unit 508 delays the signal by one sampling clock cycle or period. The output of the second delay unit 508 connects to a second multiplier 520. The second multiplier 520 also receives as an input a value β. The second multiplier 520 multiplies the second delay unit 508 output by the value β and provides the output to the second summing junction 524. The second summing junction 524 subtracts the output of the second multiplier 520 from the first summing junction 512 output and provides the resulting signal as an output y(n).

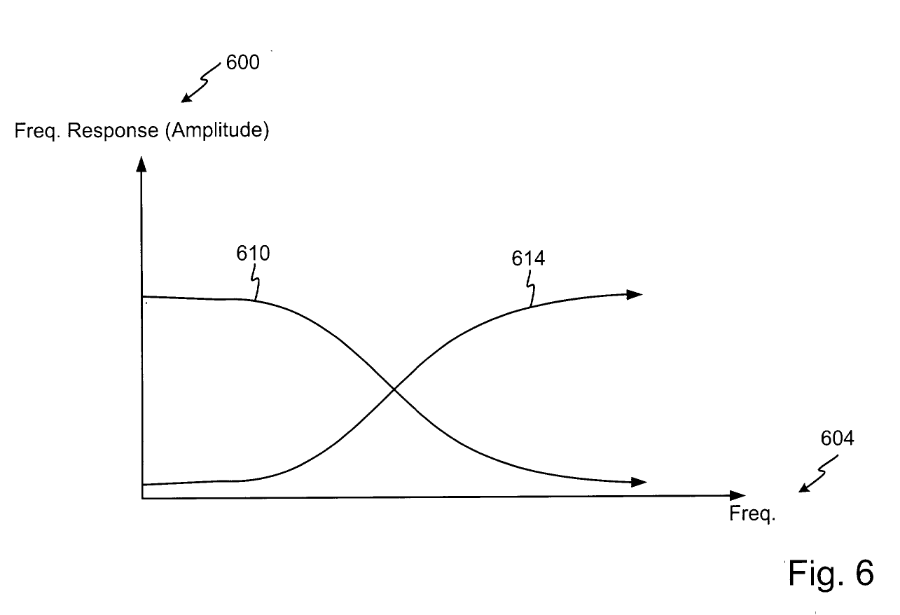

Desired operation of the equalizer shown in FIG. 5 occurs based on similar principles as described above for FIG. 4. The values of α and β may be selected and varied to tailor the frequency response of the equalizer as desired to achieve an output that is adjusted for the length, and hence the frequency response, of the transmission line. In the embodiment shown in FIG. 5, the variables α and β may assume any values as desired to achieve operation in the manner described herein. Thus, the variables may be within or outside of the range of the values zero to one. FIG. 6 illustrates an example plot of the frequency response of a hypothetical transmission line and the frequency response of a matched and adjusted equalizer system. A vertical axis 600 represents frequency response, such as a signals amplitude at various frequencies. A horizontal axis 604 represents frequency, increasing as the horizontal axis progresses to the right.

A first plot 610 represents an approximate and exemplary plot of frequency response of a long transmission line. As can be seen, the long transmission line attenuates the signal and in particular, high frequencies are attenuated more significantly. Such attenuation undesirable limits transmission distances, transmission rates, and noise margins. Attenuation of FIG. 6 is exaggerated for purposes of understanding.

A second plot 614 represents an exemplary frequency response of the equalizer system as described herein. As can be seen, the frequency response demonstrated by the second plot 614 reverses or negates the attenuation of the long transmission line shown by plot 610. Thus, through the use of the equalizer system described here the unwanted attenuation from a transmission lines may be reduced. In one embodiment the equalizer system is a pre-equalizer. Gain may be applied to the signal.

Numerous benefits may be realized by the method and apparatus described herein and claimed below. One such benefit is that of reduced complexity as compared to prior art solutions. For example, in one embodiment only two 4 bit coefficients are able to achieve what may have required a 9 tap transversal filter with coefficients on the order of 8 to 10 bits. Moreover, in one embodiment invention described herein includes the advantage of eliminating or reducing the input pattern sensitivity as compared to decision directed LMS adaptations. In addition, the method and apparatus described herein may be configured to compensate for up to 45 dB lines and in one embodiment exceeds the desired noise immunity performance by 3 dB. Furthermore, this design enjoys low power consumption as compared with analog solutions and the various designs are easy to migrate to multiport solutions.

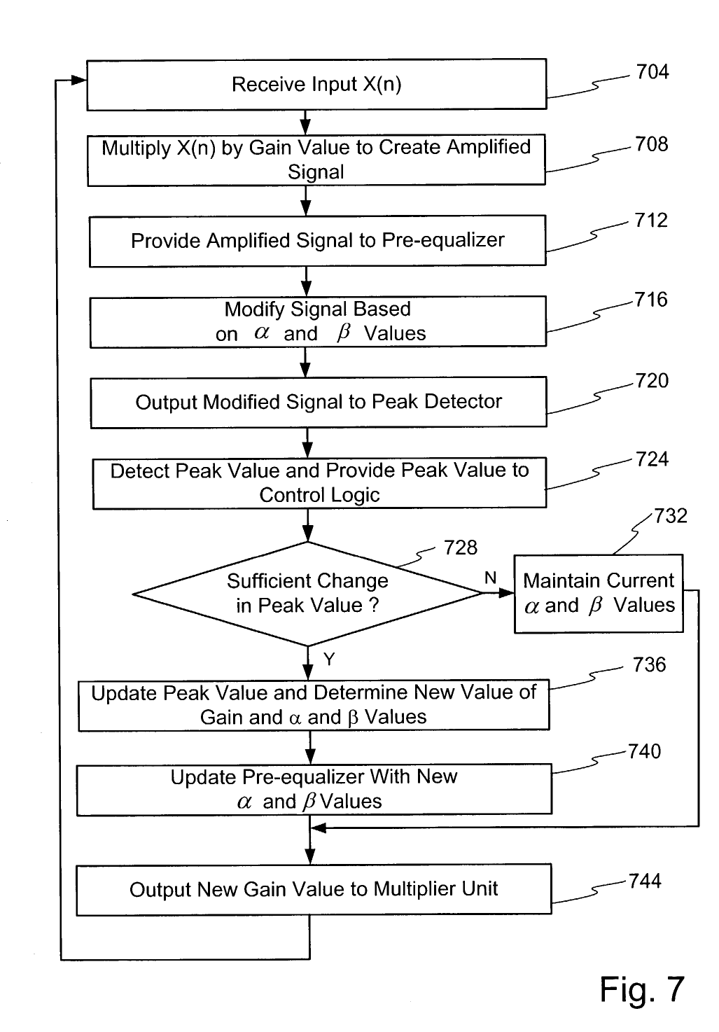

FIG. 7 illustrates an operational flow diagram of one example method of operation of the invention. This is but one possible method of operation and it is contemplated that one of ordinary skill in the art may enable other methods. At a step 704 the system receives an input X(n). At a step 708 the input is multiplied by a gain value to create an amplified signal. Other methods of amplification are contemplated. Other modification may occur in addition to or instead of the gain multiplication to create a desired signal.

At a step 712 the equalizer system provides the amplified signal to a pre-equalizer. At a step 716 the pre-equalizer modifies the signal in accordance with operation of the pre-equalizer. In the embodiment shown, the modification is frequency dependant and in accordance with the values α and β. The values α and β may be adjusted to thereby modify the frequency response of the pre-equalizer. Adjustment of the values of α and β is described above in greater detail and accordingly is not described again.

At a step 720 the system outputs the modified signal to a peak detector. The peak detector, at a step 724, detects the peak value in the received signal and provides the peak value to control logic, a controller, or a processor. Based on the peak value the channel characteristics may be determined, such as the amount of attenuation introduced by the line. In one embodiment the amount of gain required at all frequencies can be used as a basis to determine the degree of attenuation at higher frequencies. In one embodiment the frequency spectrum of the received signal may be analyzed to determine the frequency response of the channel. In one embodiment the amount of gain required at one or more frequencies to amplify the signal to a predetermined level is used as a basis to determine the degree of attenuation at higher frequencies.

At a decision step 728 the operation determines if sufficient change in the peak value has occurred to initiate a change in the values α and β. A value other than the peak value may be monitored. As discussed above, the values of α and β control the frequency response of the pre-equalizer. By increasing the values of α and β the pre-equalizer more greatly amplifies higher frequencies as compared to low frequencies. If a sufficient change has occurred in the peak value then a change in the α and β values may be warranted. Accordingly, if at step 728 the peak value has not changed or has not changed beyond a threshold, then the operation progresses to a step 732 and the existing α and β value are maintained. After step 732 the operation progresses to a step 744, which is discussed below.

Alternatively, if the peak has changed sufficiently, then the operation progresses to a step 736 wherein the control logic, processor, or controller performs a memory look-up, based on the new peak value, to obtain adjusted α and β values. In one embodiment the α and β values are referenced in table format by various peak values. In one embodiment only a α value is utilized, although in such an embodiment the pre-equalize provides less control or resolution. In one embodiment the α and β values are calculated based on process algorithms instead of being recalled from memory.

After retrieving the α and β values from memory or calculating the α and β values the system updates the pre-equalizer with the new α and β values at step 740. After step 740 the operation advances to a step 744 wherein a new gain value is derived from the new peak detector value and is provided to the multiplier unit for use in adjusting the received signal. In one embodiment the multiplier provides an equal amount of amplification to all frequencies. After step 744 the operation returns to step 704 and the operation repeats.

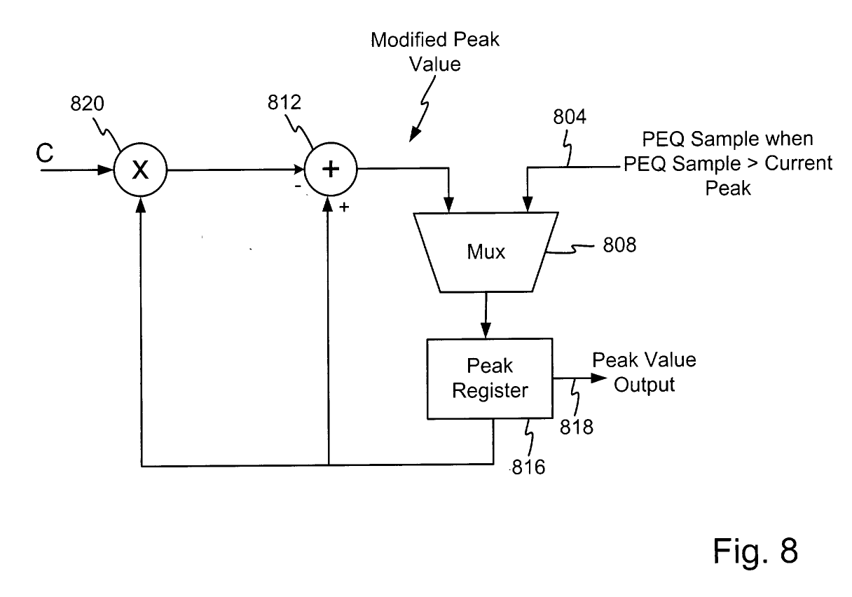

FIG. 8 illustrates a block diagram of an example embodiment of a peak value control system. This example system may optionally be included with the equalizer system described above to store or modify an instant peak value detected by the equalizer system. One aspect of the peak value control system is to provide dampening. As shown in FIG. 8, an input 804 connects to a multiplexer 808 or other control and switching device. The multiplexer 808 also receives an input from a summing junction 812, which is described below in greater detail. The multiplexer 808 outputs a value that is selected from the one or more inputs to the multiplexer.

The input signal 804 comprises the pre-equalizer sample. Basic control logic may be configured to provide this input 804 to the multiplexer 808. The input signal 808 thus provides the peak value control system the pre-equalizer sample when it exceeds the current peak value; otherwise the modified peak value is provided.

The peak register 816 may comprise any form of storage unit capable of receiving, storing, and outputting one or more data values. In one embodiment the peak register 816 comprises one or more storage registers. In one configuration the peak register 816 is 11 bits in size. The peak register 816 is configured to store the peak values as output by the multiplexer 808 and may include an output 818 that may be configured to provide the peak value to the controller 318 shown in FIG. 3.

The peak register 816 provides its output of the peak value to a summing junction 812 and a multiplier unit 820. The multiplier 820 also receives an input value C thereby causing the multiplier unit 820 to multiply the peak value by the value C. In one embodiment the value C is a small positive value of magnitude less than one. This embodiment allows the peak value to slowly settle to a lower value when the peak detector is distorted by a large value due to noise. The output of the multiplier unit 820 feeds into the summing junction 812. Although other configurations are possible, the summing junction 812 subtracts the multiplier unit 820 output from the peak value provided from the peak register 816. The resulting value is fed into the multiplexer 808 and is processed by the multiplexer as described above.

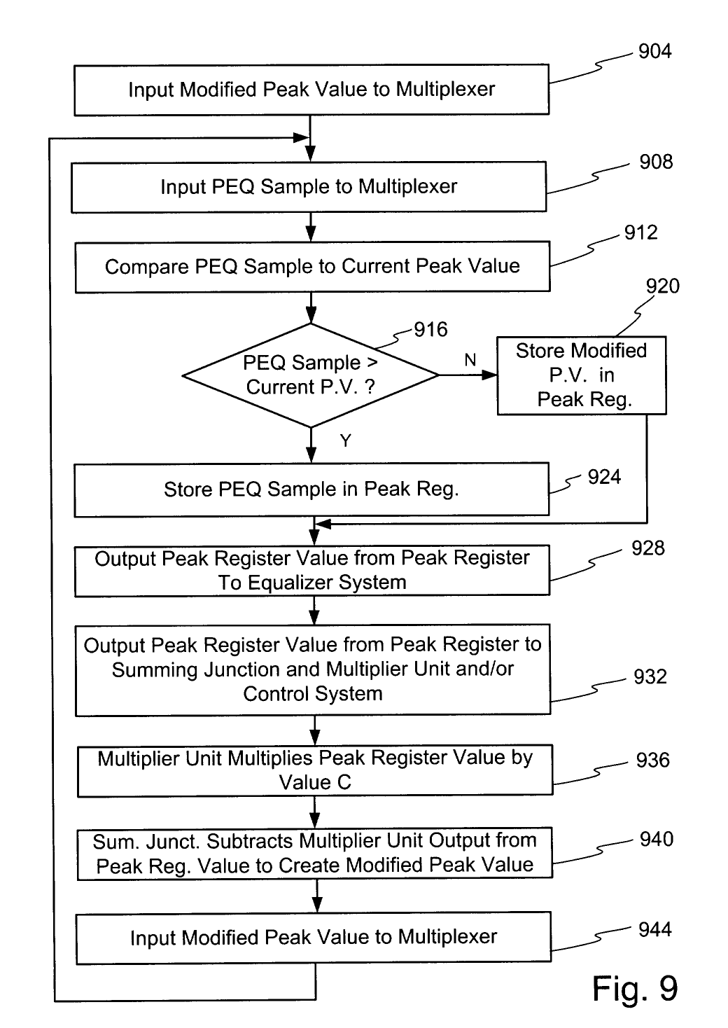

FIG. 9 is an operational flow diagram of an example method of operation of the peak value control system shown in FIG. 8. This is but one possible method of operation. Other methods of operation are contemplated and are not outside the scope of the claims. At a step 904 the peak value control system inputs the modified peak value into one of the inputs to the multiplexer. The modified peak value may comprise the value generated in the processes described below, or if at start up, a zero value, a pre-stored value, or a value calculated by the peak value control system. Next, at a step 908, the system inputs the most recent sample out of the equalizer (PEQ) to the multiplexer.

Thereafter, at a step 912, the multiplexer, comparator or other compare logic compares the PEQ sample to the current peak value. At a decision step 916 a determination is made regarding whether the most recent PEQ sample is greater than the current peak value. If the comparison reveals that the PEQ sample is greater than the current peak value then the operation advances to a step 924. At a step 924, the system stores the PEQ sample in peak a register and thereafter advances to a step 928.

Alternatively, if at step 916 it is determined that the current peak value is greater than the PEQ sample than the operation advances to a step 920. At step 920, the operation stores the modified peak value in the peak register.

At a step 928 the system outputs the peak register contents or value to the equalizer system and/or the control system. At a step 932 the peak register contents or value is provided to a summing junction and multiplier unit. The multiplier unit multiplies the peak register value by a value C. The value C may be selected to comprise any value. In one embodiment the value C comprises a value between zero and 0.5. Other values may be selected as desired. Multiplying the peak value by a value C creates an output that is a function of the peak value and which is less than the peak value when C is selected to be less than 1. This value is provided to the summing junction. By selecting C to be a small value the output of the multiplier is a small value.

At a step 940 the summing junction subtracts the multiplier unit output from the peak register value to create a modified peak value. This operation in effect reduces or bleeds down what was previously the peak value to create the modified peak value. This also creates a dampening effect on the reduction of the modified value. As a result, sudden reductions in the detected peak value will not result in a sudden change in the peak value provided to the equalizer system. Thereafter, at a step 944 the operation inputs the modified peak value into the multiplexer. The multiplexer then uses this value during the next reiteration. After step 944 the operation returns to step 908. It is contemplated that the operation may repeatedly occur during ongoing operation of the equalizer system.

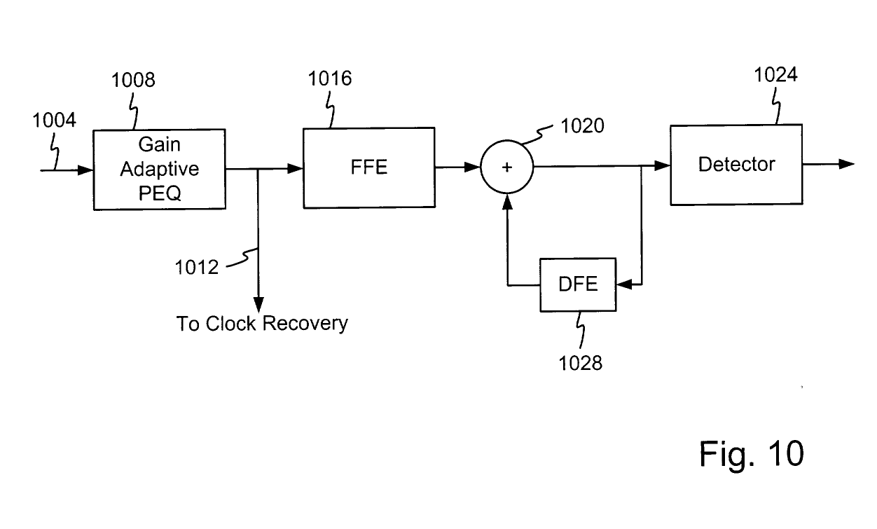

FIG. 10 illustrates an alternative embodiment of the invention. This embodiment has numerous similarities to the above-described systems and as a result, differences in this embodiment are discussed in more detail while previously described aspects are not described in as great a detail. While this embodiment is shown in conjunction with a system operating under the digital subscriber line (DSL) standard, it is contemplated it may operate with any type communication system. As shown, an input 1004, which may connect to a channel or transmission line connects to an adaptive pre-equalizer 1008. The adaptive pre-equalizer 1008 is similar in configuration to the equalizer system shown in FIG. 2 or 3. The adaptive pre-equalizer 1008 is configured to analyze the received signal to gain information regarding the channel. Based on the analysis, the adaptive equalizer 1008 processes the signal to account for channel characteristics. In one embodiment the basis for the processing is based on a signal's relation to a threshold value.

In one configuration this embodiment is implemented with a system, such as certain DSL systems, that employs a signal modulation and transmission scheme that randomly or otherwise varies and selects voltage values of the transmitted signal to transmit a generally average voltage level over time. As a result, various configurations of this embodiment may be well suited for such modulation and transmission schemes. One example of such a system comprises a transmitter system with a scrambler. One example modulation scheme is pulse code modulation (PAM). Thus, in contrast to the prior embodiment shown in FIG. 3, which detected a peak value and performed equalization based on the peak value, the embodiment of FIG. 10 may monitor a threshold value and select or adapt the adaptive pre-equalizer settings based on the threshold or average value. Since a threshold or average value is detected, it may desired to utilize a scrambler or other similar device. In one embodiment the adaptive pre-equalizer 1008 utilizes two coefficients α and β to control processing, however the adaptive pre-equalizer may be configured to utilize any number of coefficients. In one embodiment the adaptive pre-equalizer 1008 may include feedback gain and the equalizer coefficients are based on the amount or level of gain. In another embodiment the equalizer coefficients are based on a comparison of the received signal to a threshold signal.

Returning to FIG. 10, the output of the adaptive pre-equalizer 1008 is provided to a feed forward equalizer (FFE) 1016. In one embodiment the FFE 1016 performs least mean squares adaptive filtering as is understood by one of ordinary skill in the art. One advantage of the method and apparatus described herein is that the FFE 1016 can be made less complex by inclusion of the adaptive equalizer 1008. As a further advantage, the adaptive equalizer 1008 modifies the received signal to facilitate more accurate clock recovery, which improves overall receiver operation.

A summing junction 1020 receives the output of the FFE 1016 and is configured to combine the FFE output with a feed back subject to decision feedback equalizer 1028 (DFE) processing. The output of the summing junction 1020 is provided to a detector and to an input of the DFE 1028. In one embodiment the DFE 1028 serves as a predictive filter to predict the intersymble interference caused by or from line distortion. This interference is subtracted from the received signal by the summing junction 1020. The detector 1024 receives the processed signal and compares it to one or more decision thresholds for the purpose of estimating the signal value that was transmitted from the other end of the transmission line. This decision is the input to the DFE.

It is further contemplated that modification may optionally be made to the system of FIG. 10 to provide greater compatibility with various communication standards. For example, with a DSL system with power back-off capability additional look-up tables may aid in adjusting the coefficients to the desired level. In such a system if the power is backed off by the DSL system then the gain of the adaptive pre-equalize may be adjusted to compensate as more gain will be required to increase the signal level to a level as desired for processing. The low signal power level is, however, not a result of line losses, i.e. it is not from a long line, and thus the adaptive pre-equalizer 1008 should not compensate as if the losses were from a long line or other aspect that does not effect all frequencies equally. Thus, for systems that change transmit power levels additional look-up tables or calculations may be necessary.

Moreover, it is contemplated that different line codes for the different transmission standards or protocols may require different look-up tables. By way of example and not limitation, the following communication protocols HDSL, ANSI HDSL2, and ITU G.SHDSL all have different transmit spectrums and may benefit from look-up tables tailored to each standard or protocol. Hence for different transmit spectrums different α and β values may be stored in memory and chosen to achieve desired equalization. The α and β values may be adjusted or changed in real time during operation as part of a look-up operation.

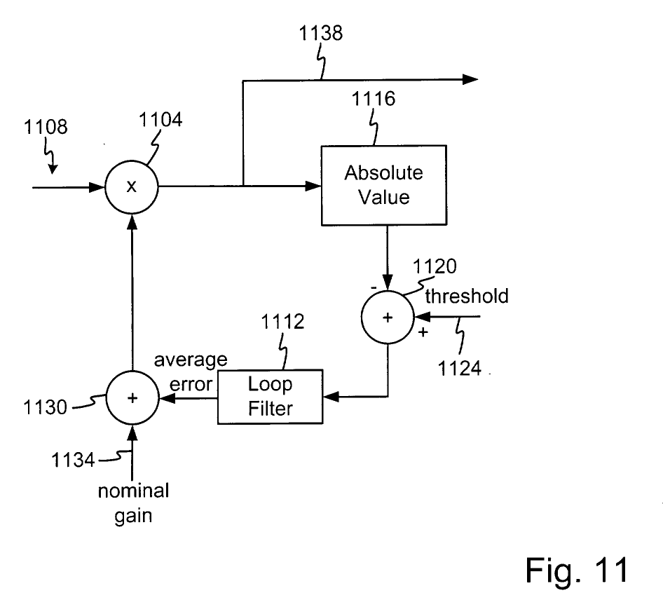

FIG. 11 illustrates a block diagram of an example embodiment of an automatic gain control loop using a threshold instead of a peak detector. In one embodiment the threshold detector replaces the peak detector as shown in FIG. 2 and FIG. 3. FIG. 11 illustrates a multiplying unit 1104 configured to receive an input signal from an input line 1108. In one embodiment the input signal is received from a transmission line, channel or other medium. The multiplying unit 1104 also receives an input from a second summing junction 1130, which is discussed below in greater detail. The output of the multiplying unit 1104 feeds into an absolute value unit 1116. The absolute value unit 1116 is configured to determine the absolute value, i.e. non-negative value, of its input and provide the absolute value as an output to a summing junction 1120 to be combined with a threshold value 1124. The absolute value unit 1116 output is subtracted from the threshold value input 1124. The threshold value 1124 comprises a signal value or level that serves as a standard or references value to which the incoming signal is compared. In one embodiment it is desired that the average magnitude of the output of the equalizer system be at the threshold value. The summing junction 1120 provides its output to a loop filter 1112. In one embodiment the loop filter 1112 is configured to generate an average error over time. In one embodiment the filter 1112 comprises an integrator with a built-in scaling factor. The output of the filter feeds into summing junction 1130. The summing junction 1130 combines the output of the loop filter 1112 with a nominal gain value 1134. In this embodiment the nominal gain value comprises a value generally close to one and is the desired gain for the loop system. Summing the nominal gain value with the average error of the loop filter 1112 results in a value for use by the multiplier 1104 to adjust that gain applied to the signal received on line 1108. The nominal gain value may be dependant on the communication system, transmit power level, or type of line code in use.

The output of the summing junction 1130 is provided to the multiplying unit 1104 described above. After loop processing of the system of FIG. 11, the output of the multiplying unit 1104 is provided as an output to the equalizer system on output line 1138 and as an input into the absolute value unit 1116. The output on output line 1138 may be provided to an equalizer filter, such as a pre-equalizer, for additional processing. Coefficients for an equalizer filter, such as a pre-equalizer, may be selected by the amount of adjustment to the signal that is required to return the signal to a predetermined value or based on the difference between the received signal and a threshold value 1124. The threshold value 1124 maybe a desired or expected signal level.

In one embodiment a second multiplying unit (not shown) is placed between the filter 1112 and the summing junction 1120. The second multiplying unit multiplies the output of the summing junction 1120 by a small value. This configuration prevents a large error value from creating a large and sudden change in the output of the threshold detector.

While various embodiments of the invention have been described, it will be apparent to those of ordinary skill in the art that many more embodiments and implementations are possible that are within the scope of this invention.

What is claimed is:

1. An equalizer configured to process a received signal comprising:
an amplifier configured to amplify the received signal to create an amplified signal at a predetermined power level, the amount of amplification determined by a gain value;
a filter configured to modify the amplified signal on a frequency dependant basis to generate a filtered signal, the filter responsive to one or more coefficients;
a control unit configured to:
generate the gain value based on the magnitude of the received signal, the amplified signal, or the filtered signal; and
obtain the one or more coefficient values based on the gain value.

2. The equalizer of claim 1, wherein the filter comprises a two tap transversal filter.

3. The equalizer of claim 1, wherein the amplifier is configured to amplify all frequencies an equal amount.

4. The equalizer of claim 1, further including a memory configured to store the one or more coefficient values wherein the control unit is configured to analyze the gain value and, based on the gain value, retrieve the one or more coefficient values from the memory and provide the one or more coefficient values to the filter.

5. The equalizer of claim 1, wherein the filter is configured to amplify or attenuate on a frequency dependant basis.

6. A transmission line equalizer comprising:
an amplifier configured to amplify a received signal based on a gain value to create an amplified signal;
an equalizer configured to receive one or more coefficients and modify the amplified signal based on the one or more coefficients;
a peak detector configured to receive feedback from the equalizer and determine a peak value of the received signal, the amplified signal, or the feedback; and
a controller, connected to the peak detector and responsive to the peak value, configured to provide the one or more coefficients to the equalizer.

7. The transmission line equalizer of claim 6, wherein the equalizer is configured to increase modification to a high frequency portion of the amplified signal as the peak value, detected by the peak detector, decreases.

8. The transmission line equalizer of claim 6, further including a memory in communication with the controller, the memory configured to store one or more coefficients.

9. The transmission line equalizer of claim 6, wherein the equalizer comprises a transversal filter equalizer.

10. The transmission line equalizer of claim 6, wherein the gain value of the amplifier is determined by comparing the magnitude of the received signal to a threshold wherein the theshold is an average magnitude of the signal And the one or more coefficients are based on the gain value.

11. The transmission line equalizer of claim 6, wherein the one or more coefficients create an equalizer having a frequency response inverse to the transmission line.

12. A computer program product comprising a computer useable medium having computer program logic recorded thereon for providing signal analysis and compensation, comprising:
computer program code logic configured to analyze a signal received over a channel to determine a gain level required restore the signal to predetermined level;
computer program code logic configured to perform a look-up operation in a memory to obtain one or more filtering control values based on the gain level; and
computer program code logic configured to filter the signal based on the filtering control values to selectively amplify or attenuate portions of the signal.

13. The computer readable medium of claim 12, wherein the predetermined level comprises a signal power level at which the signal was transmitted.

14. The computer readable medium of claim 12, wherein the computer program control logic configured to filter the signal executes on a digital signal processor.

15. The computer readable medium of claim 12, wherein the computer program control logic configured to filter comprises computer program control logic configured to increase the power level of high frequency portions of the signal as the gain level increases.

16. A system for reversing attenuation of a signal resulting form transmission through a channel, the system comprising:
a comparator configured to compare one or more aspects of the signal to one or more predetermined values;
a memory configured to store coefficient values;
a controller in communication with the comparator wherein the controller is configured to retrieve from the memory one or more coefficient values based on the comparison performed by the comparator; and
a filter connected to the controller, wherein the filter, responsive to the one or more coefficient values, reverse the effects of the channel.

17. The system of claim 16, wherein the filter comprises an adaptive filter configured to utilize three or more coefficient values.

18. The system of claim 16, wherein the comparator compares a peak value of the signal to one or more reference values to determine which of the one or more coefficient values to retrieve from memory.

19. The system of claim 16, wherein the comparator compares a threshold value of the signal to one or more reference values to determine which of the one or more coefficient values to retrieve from memory.

20. The system of claim 16, wherein the controller comprises a processor.

21. The system of claim 16, further including a dampening circuit configured limit the maximum rate of change for the one or more coefficient values.

22. A method for processing a received signal to negate the effect on the signal from transmission through a channel comprising:
receiving a signal;
analyzing the amplitude of the signal to determine an amount of effect on the signal from transmission through the channel;
generating or retrieving one or more filter coefficients based on the amount of effect; and
filtering the signal, based on the one or more filter coefficients, to adjust the power level of the signal, on a frequency dependant basis, to thereby negate the effect on the signal from transmission through the channel.

23. The method of claim 22, wherein generating or retrieving one or more filter coefficients comprises retrieving one or more filter coefficients from a memory storing two or more filter coefficients.

24. The method of claim 22, wherein the generating or retrieving comprises one or more filter coefficients from a memory based on a gain value.

25. The method of claim 22, wherein analyzing the signal comprises detecting a peak value of the signal and the generating or retrieving one or more filter coefficients from a memory is based on the peak value.

26. The method of claim 22, wherein analyzing the signal comprises comparing a magnitude of the signal to a threshold wherein the threshold is based on an average magnitude of the signal.

27. The method of claim 22, wherein as the amplitude of the signal decreases the filtering increases the power level of high frequency portions of the signal more so than low frequency portions of the signal.

28. A method for adjusting the power level of signal portions located at different frequencies to offset the effect on the signal portions resulting from transmission through a channel, the method comprising:
receiving one or more signal portions, the signal portions comprising a signal transmitted over the channel;
amplifying the one or more signal portions based on a gain control value, the amplifying intended to increase the power level of the one or more signal portions to a predetermined power level,
analyzing the one or more signal portions to determine the gain control value;
generating one or more filter coefficients based on the gain control value; and
modifying at least one of the one or more signal portions on a frequency dependant basis, based on the one or more filter coefficients, to offset the effect of transmission through the channel.

29. The method of claim 28, wherein the analyzing comprises determining a peak power level or an average power level of one or more signal portions.

30. The method of claim 29, further including comparing the peak power level or the average power level to predetermined values and the generating comprises retrieving, based on the comparison, filter coefficients from a memory configured to stored filter coefficients.

31. The method of claim 28, wherein the modifying is performed by a pre-equalizer configured to utilize two filter coefficients.

32. The method of claim 28, wherein amplifying amplifies all signal portions and wherein modifying the signal comprises modifying high frequencies portions of the signal more than low frequency portions of the signal.

33. The method of claim 28, wherein the generating one or more filter coefficients comprises comparing the gain value to one or more stored values and based on the comparison retrieving one or more filter coefficients from a memory.

34. A pre-equalizer system for reversing changes to a signal transmitted through a transmission line, the system comprising:
means for receiving a signal;
means for analyzing the signal;
means for characterize the channel based on analyzing the signal;
means for storing one or more coefficients;
means for retrieving one or more coefficients from the means for storing based on the characterization of the channel; and
means for modifying the signal on a basis that is generally inversely proportional to the effect of transmission of the signal through the channel to thereby create a modified signal, the degree of modification performed by the means for modifying determined by the one or more coefficients.

35. The pre-equalizer system of claim 34, wherein the means for characterizing the channel comprises means for calculating an amplification level applied to the signal.

36. The pre-equalizer system of claim 34, wherein the means for characterizing comprises a peak detector and a comparator.

37. The pre-equalizer system of claim 34, wherein the means for modifying comprises a filter.
